(19) United States
(12) Patent Application Publication
(10) Pub. No.: US 2016/0124025 A1
(43) Pub. Date: May 5, 2016

(54) CURRENT SENSOR ARRANGEMENT WITH MEASURING COILS

(71) Applicant: Phoenix Contact GmbH & Co KG, Blomberg (DE)

(72) Inventors: Peter SCHOLZ, Brakel (DE); Elmar SCHAPER, Lügde (DE)

(73) Assignee: Phoenix Contact GmbH & Co KG, Blomberg (DE)

(21) Appl. No.: 14/895,294

(22) PCT Filed: Jun. 4, 2014
(86) PCT No.: PCT/EP2014/061564

§ 371 Date: Dec. 2, 2015

(30) Foreign Application Priority Data
Jun. 12, 2013 (DE) 10 2013 106 100.1

(51) Int. Cl. G01R 15/18; G01R 19/00

(52) U.S. Cl. CPC G01R 15/181; G01R 19/0092

(57) ABSTRACT

The invention relates to a current sensor arrangement having a measuring inductance (103), said measuring inductance having the following characteristics: a first measuring coil (105); a second measuring coil (107); the first measuring coil (105) and the second measuring coil (107) being electrically connected in rows and having different coil properties.

The invention relates to the field of inductive current measurement.

It is necessary to measure current in multi-phase conductor systems, for example three-phase conductor systems, in order to detect short circuits, for example, and to enable protection against short circuits for the electrical loads connected to a multi-phase conductor system such as e.g. motors or heating elements.

In the context of short-circuit protection, the IEC 60947-4-1 standard differentiates between two classification types. In classification type 1, contactors or semiconductor switching devices can for example be destroyed if they do not pose any risk such as fire or open live parts. In classification type 2, however, downstream devices need to remain functional, whereby user intervention such as breaking contact points using simple tools may be necessary. While mechanical switching devices such as for example contactors are frequently assigned to classification type 2, classification type 1 is usually applicable to semiconductor switching devices, for example motors.

Either current transformers, magnetic field sensors or current sensors can be used to measure current in multi-phase conductor systems.

Rogowski coils, also called Rogowski current transformers, can for example be used as current sensors. A Rogowski coil comprises a toroid measuring coil with an air core. To measure current, a current-conducting lead is enclosed by the Rogowski coil, whereby an electrical voltage is generated in the measuring coil due to the current flowing in the current-conducting lead.

Yet when measuring current in a multi-phase conductor system, magnetic interference fields are generated due to the currents flowing in adjoining current-conducting leads and these can falsify a current measurement from a conventional Rogowski coil. In addition, due to their toroid coil form, Rogowski coils cannot be used in multi-phase conductor systems disposed in a planar arrangement on a circuit board.

It is thus the task of the present invention to provide an improved current sensor which is also able to be used in a multi-phase conductor system.

This task is solved by the features of the independent claims. Advantageous embodiments of the invention form the subject matter of the dependent claims, the accompanying figures and the description.

According to one aspect, the invention relates to a current sensor arrangement comprising a measuring inductor, whereby the measuring inductor has the following features: a first measuring coil and a second measuring coil, wherein the first measuring coil and the second measuring coil are electrically connected in series and have different coil properties.

The measuring coils of the measuring inductor can be configured for example as measuring coils or as spatially extended measuring coils, e.g. at least partly toroid coils.

The measuring coils can further be spatially related and together form e.g. a toroid shape and thus a modified Rogowski coil.

The measuring coils can however be spatially distanced from one another and form a gap which is bridged by means of the winding-free connecting section. The gap serves to receive the current-conducting lead, the current of which is to be measured. The current-conducting lead thus intersects the winding-free connecting section which runs above or below said current-conducting lead. According to one embodiment, the measuring inductor can thus be construed as a modified Rogowski coil.

According to one embodiment, the first measuring coil and the second measuring coil have different inductances, different numbers of windings, different surface areas or different coil diameters.

According to one embodiment, the first measuring coil and the second measuring coil are electrically connected via a winding-free section.

According to one embodiment, the first measuring coil is planar and has windings arranged in a first plane, wherein the second measuring coil is planar and has windings arranged in a second plane.

According to one embodiment, the first windings are of planar helical, spiral or meander structure in the first plane, e.g. coiled, and the second windings are of planar helical, spiral or meander structure in the second plane, e.g. coiled. With an increasing number of windings or pitch, the spatial extension of the respective measuring coil thus also increases, in particular the surface which a magnetic current is able to penetrate. An overall induction-active cross section of the respective measuring coil can thus be provided in particularly advantageous manner.

According to one embodiment, the first windings and the second windings are formed, e.g. coiled, in opposite directions. Doing so thereby recreates the mechanism of a Rogowski coil.

According to one embodiment, the first measuring coil and the second measuring coil can be arranged on both sides of a current-conducting lead. The current-conducting lead is thus not enclosed by the measuring inductor but instead runs for example in the same plane as the measuring coils arranged on both sides.

According to one embodiment, the first plane and the second plane are in a parallel arrangement; i.e. they do not intersect, or they lie in the same plane respectively, or they run at a predetermined angle to one another, e.g. 10°, 30°, 45° or 90°.

According to one embodiment, the current sensor arrangement comprises a connection terminal having a first measuring connection, which is connected to the first measuring coil, and a second measuring connection which is electrically connected to the second measuring coil by means of a second winding-free connecting section. The second winding-free connecting section thus bridges the distance between the measuring coils.

According to one embodiment, the current-conducting lead can be arranged above or below the respective winding-free connecting section. The length of the respective winding-free connecting section thus corresponds at least to the width of the current-conducting lead.

According to one embodiment, the measuring inductor is arranged on or in a circuit board, wherein the first windings, the second windings and the respective winding-free connecting section are formed by striplines, particularly printed striplines, thus advantageously providing a circuit board measuring arrangement.

According to one embodiment, the current sensor arrangement comprises a second measuring inductor and a third measuring inductor, whereby the second measuring inductor comprises a third measuring coil and fourth measuring coil having different electrical properties, whereby the third measuring inductor comprises a fifth measuring coil and a sixth measuring coil having different electrical properties, and whereby each measuring inductor is provided to measure a current in a respective current-conducting lead of a multi-phase conductor system.

According to one embodiment, the first measuring coil and the second measuring coil are arranged on both sides of the first current-conducting lead of the multi-phase conductor system, whereby the third measuring coil and the fourth measuring coil are arranged on both sides of the second current-conducting lead of the multi-phase conductor system, and whereby the fifth measuring coil and the sixth measuring coil are arranged on both sides of the third current-conducting lead of the multi-phase conductor system.

The measuring coils of the second measuring inductor and third measuring inductor can incorporate the features of the corresponding measuring coils of the first measuring inductor. The measuring inductors can be of planar form or spatially extended in or on a common circuit board.

According to one embodiment, the first measuring coil and the second measuring coil are arranged on both sides of a first current-conducting lead of the multi-phase conductor system, whereby the third measuring coil and the fourth measuring coil are arranged on both sides of a second current-conducting lead of the multi-phase conductor system, and whereby the fifth measuring coil and the sixth measuring coil are arranged on both sides of a third current-conducting lead of the multi-phase conductor system. Doing so thus realizes a measuring arrangement for measuring current in a multi-phase conductor system.

According to one embodiment, the measuring inductor is arranged adjacent to the second measuring inductor and the second measuring inductor is arranged adjacent to the third measuring inductor, whereby the second measuring coil and the third measuring coil can be arranged at different distances to the first current-conducting lead and to the second current-conducting lead, and whereby the fourth measuring coil and the fifth measuring coil can be arranged laterally adjacently at different distances to the second current-conducting lead and to the third current-conducting lead.

According to one embodiment, the second measuring coil and the third measuring coil are arranged adjacent each other at different distances to the first current-conducting lead or to the second current-conducting lead, whereby the fourth measuring coil and the fifth measuring coil are arranged adjacent each other at different distances to the second current-conducting lead or to the third current-conducting lead. The measuring inductors are thus aligned adjacent one another and in a row. The current-conducting leads run between the respective measuring coils of the measuring inductors. The increased distances between measuring inductors reduces current interference in adjacent current-conducting leads.

According to one embodiment, the second measuring inductor is laterally offset relative to the measuring inductor and relative to the third measuring inductor, particularly in the direction of extension of the second current-conducting lead. The measuring inductors are thus laterally arranged one behind the other. This thereby provides a particularly space-saving arrangement of the measuring inductors.

According to one embodiment, the third measuring coil is arranged directly adjacent the first current-conducting lead and the fourth measuring coil is arranged directly adjacent the third current-conducting lead. This thereby allows for the arrangement of the measuring coils even given closely positioned current-conducting leads, for example on a circuit board.

According to one embodiment, the current-conducting leads of the multi-phase conductor system run through the vertices of a geometrical triangle. The second measuring inductor and the third measuring inductor are arranged at vertices of the notional planar geometrical triangle. The measuring inductors are thus arranged symmetrically to one another such that interference originating from respective other current-conducting leads can be effectively suppressed. Additionally, the geometrical extending and/or numbers of windings of the second, fourth and sixth measuring coil, which are arranged within the notional triangle, can be reduced.

According to one embodiment, the second measuring coil has a smaller coil diameter or fewer windings than the first measuring coil, the fourth measuring coil has a smaller coil diameter or fewer windings than the third measuring coil and the sixth measuring coil has a smaller coil diameter or fewer windings than the fifth measuring coil. Doing so can effectively reduce the effects of stray magnetic fields.

According to one embodiment, respective measuring inductors are designed to emit an output signal, particularly an output voltage or an output current, which is in each case dependent upon the intensity of the current in the respective current-conducting lead, wherein the current sensor arrangement further comprises a monitoring device designed to monitor the exceedance of a current threshold by an electric current in the respective current-conducting lead based on the output signal of the respective measuring inductor.

According to one embodiment, the monitoring device comprises the following features: a first monitoring path for receiving the output signal of the measuring inductor with a first threshold detector and a first diode downstream of the first threshold detector; a second monitoring path for receiving the output signal of the second measuring inductor with a second threshold detector and a second diode downstream of the second threshold; a third monitoring path for receiving the output signal of the third measuring inductor with a third threshold detector and a third diode downstream of the third threshold; and a control connection with which the cathode of the first diode, the cathode of the second diode and the cathode of the third diode are electrically connected; wherein the respective threshold detector is configured to generate an output current upon exceeding a threshold by a current represented by the respective output signal.

According to one embodiment, the current sensor arrangement comprises a short-circuit generating device downstream of the control connection and designed to short circuit at least one of the current-conducting leads, particularly for a predetermined short-circuit interval, in response to an output current at the control connection.

Reference will be made to the accompanying drawings in defining further embodiments. Shown are:

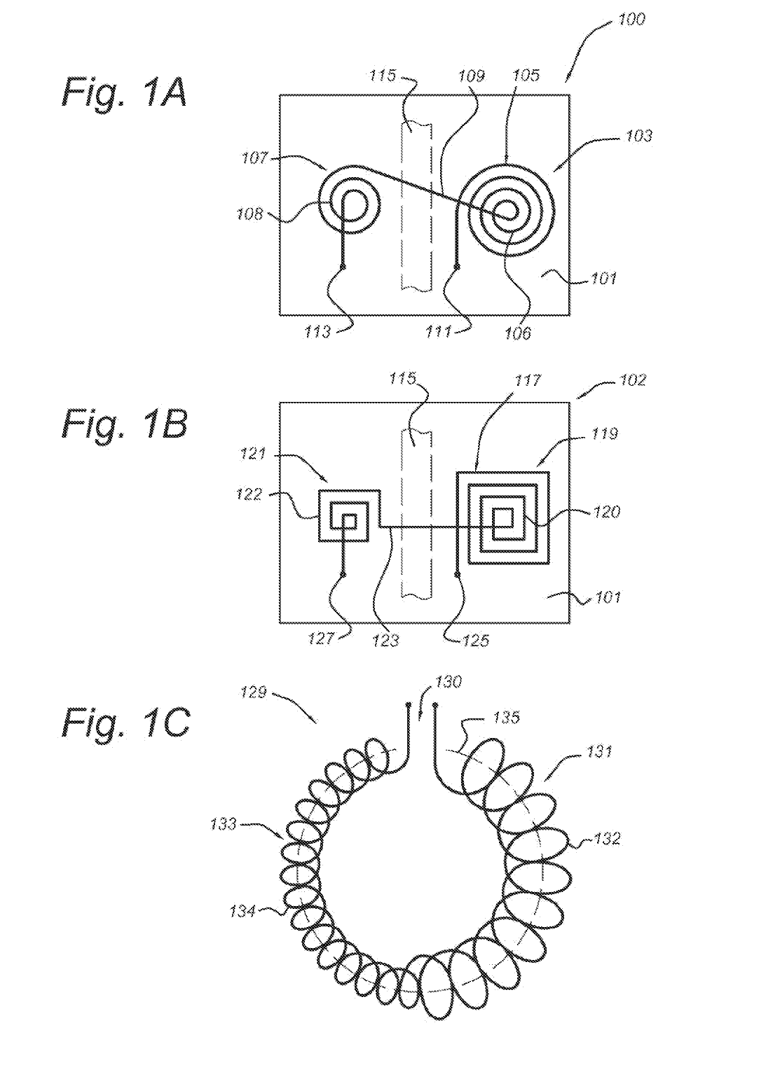

FIG. 1A, 1B, 1C current sensor arrangements;

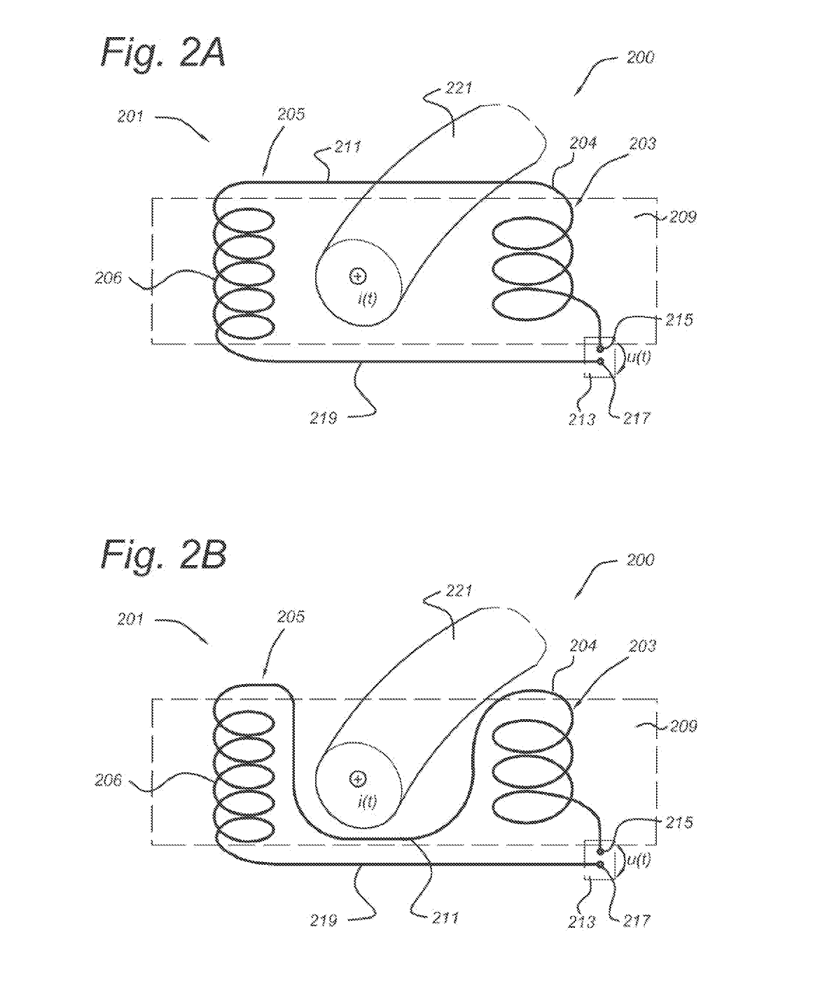

FIG. 2A, 2B current sensor arrangements;

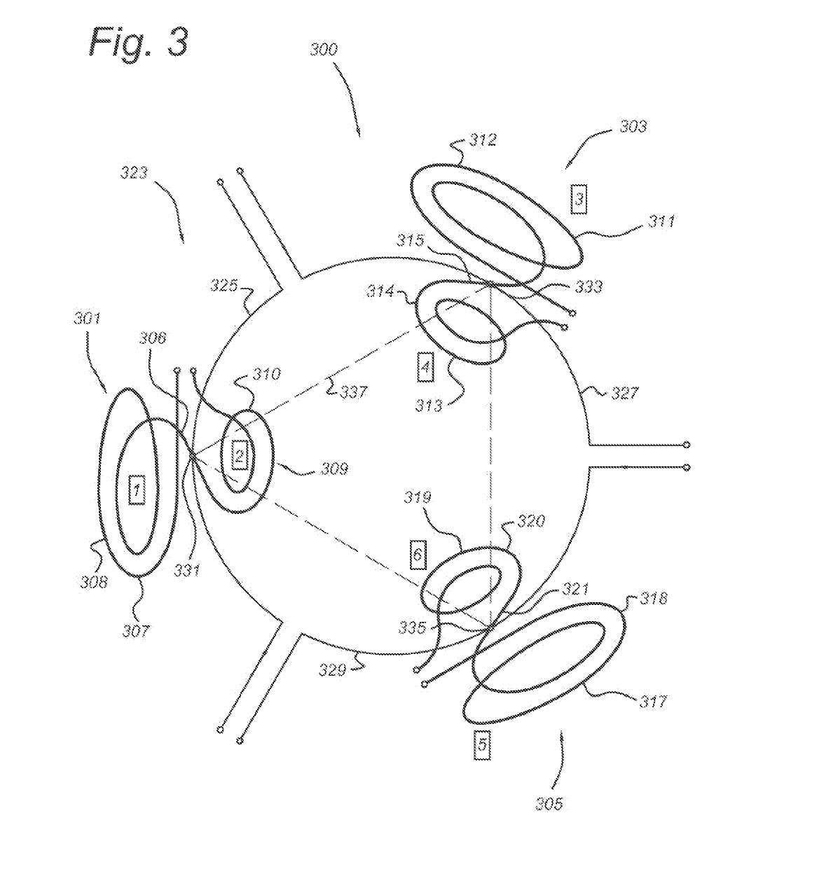

FIG. 3 a current sensor arrangement;

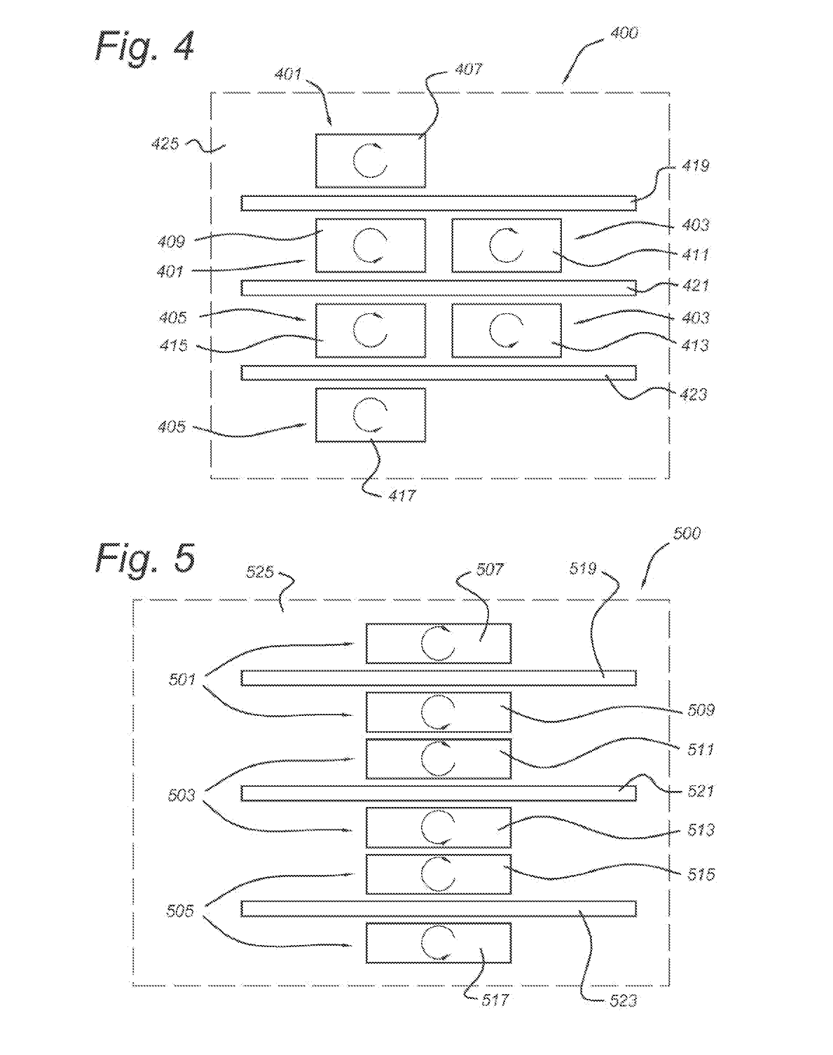

FIG. 4 a current sensor arrangement;

FIG. 5 a current sensor arrangement;

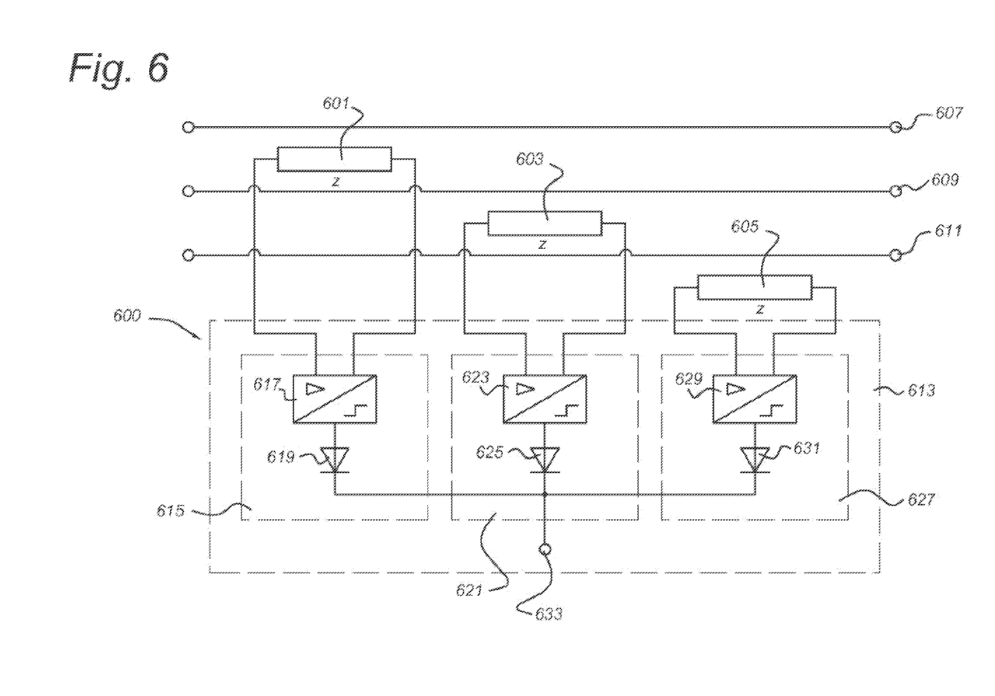

FIG. 6 a current sensor arrangement; and

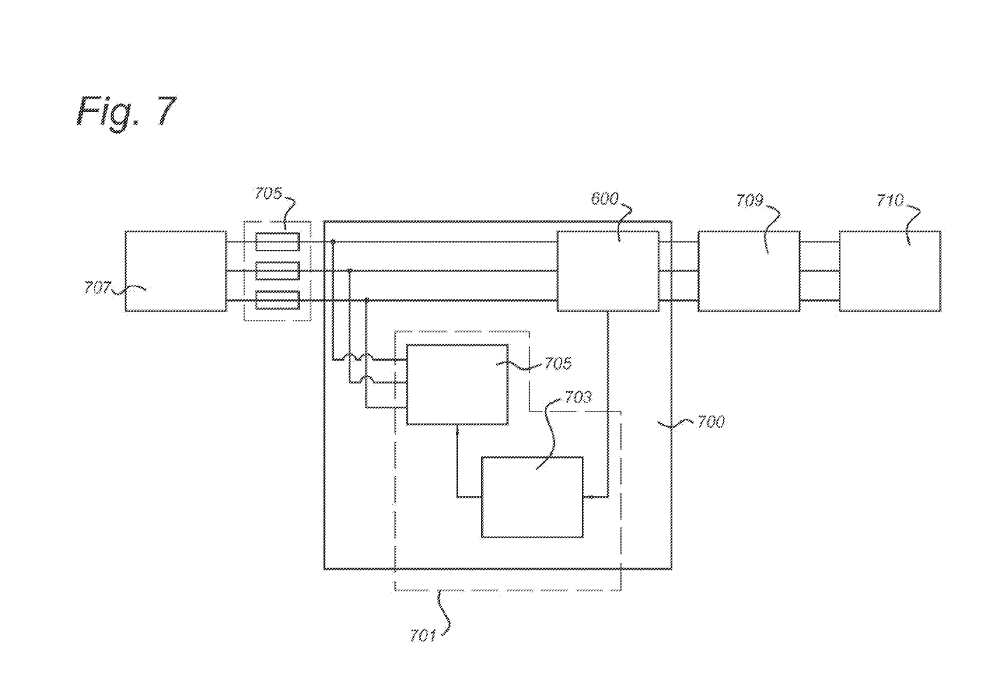

FIG. 7 a current sensor arrangement.

FIG. 1A shows a current sensor arrangement 100 comprising one measuring inductor 103, whereby the measuring inductor 103 comprises a first measuring coil 105 with first windings 106 which are arranged in a first plane, a second measuring coil 107 with second windings 108 arranged in a second plane, and a winding-free connecting section 109 which electrically connects the first measuring coil 105 to the second measuring coil 107 in series. The first plane and the second plane are for example parallel; i.e. the measuring coils 105, 107 are arranged in the same plane.

The first measuring coil 105 can for example have more windings and/or a larger coil diameter than the second measuring coil 107 and/or a surface penetrable by magnetic flux.

Measuring inductor 103 can be in planar arrangement on a circuit board 101 or arranged spatially in the circuit board 101.

The winding-free connecting section 109 is for example a straight or curved conductive piece albeit without any windings.

In the example depicted in FIG. 1A, the windings 106, 108 of the measuring coils 105, 107 are helical and of opposite configuration, e.g. coiled. The windings 106, 108 can have the same or different diameters and/or the same or different numbers of windings.

A current-conducting lead 115 can be arranged between the measuring coils 105, 107 such that the measuring coils 105, 107 are arranged on both sides of the current-conducting lead 115. The current-conducting lead 115 furthermore intersects with the winding-free connecting section 109 connecting the measuring coils 105, 107.

FIG. 1B shows a current sensor arrangement 102 comprising one measuring inductor 117, whereby the measuring inductor 117 comprises a first measuring coil 119 with first windings 120 which are arranged in a first plane, a second measuring coil 121 with second windings 122 arranged in a second plane, and a winding-free connecting section 123 which electrically connects the first measuring coil 119 to the second measuring coil 121 in series. The first plane and the second plane are for example parallel; i.e. the measuring coils 119, 121 are arranged in the same plane. The winding-free connecting section 123 is for example a straight or curved conductive piece, albeit without any windings.

In the example depicted in FIG. 1B, the windings 120, 122 of the measuring coils 119, 121 are helical and of opposite configuration. The windings 120, 122 can have the same or different diameters and/or the same or different numbers of windings.

A current-conducting lead 115 can be arranged between the measuring coils 105, 107 such that the measuring coils 105, 107 are arranged on both sides of the current-conducting lead 115. The current-conducting lead 115 furthermore intersects the winding-free connecting section 109 connecting the measuring coils 105, 107.

The first measuring coil 119 can for example have more windings and/or a larger coil diameter than the second measuring coil 121 and/or a surface penetrable by magnetic flux.

Measuring inductor 117 can be in planar arrangement on a circuit board 101 or arranged spatially in the circuit board 101.

According to one embodiment, however, the measuring coils depicted in FIGS. 1A and 1B extend spatially, for example cylindrically.

FIG. 1C shows a current sensor arrangement 129 comprising one measuring inductor 130, whereby the measuring inductor 130 comprises a first measuring coil 131 with first windings 132 and a second measuring coil 133 with second windings 134. The first measuring coil 131 and the second measuring coil 133 together form a toroid shape having a core 135. The core 135 can for example be an air core or a magnetically soft core. The first measuring coil 131 can for example have more windings and/or a larger coil diameter than the second measuring coil 133 and/or a surface penetrable by magnetic flux. The first measuring coil 131 and the second measuring coil 133 are connected in series and thus form according to one embodiment a modified Rogowski coil.

FIGS. 2A and 2B show a current sensor arrangement 200 comprising one measuring inductor 201. The measuring inductor 201 comprises a first measuring coil 203 with windings 204 and a second measuring coil 205 with windings 206 which are formed as conductive paths, e.g. striplines, of a circuit board 209. The radii of the windings 204, 206 and/or the number of windings to the respective windings 204, 206 can be the same or different.

The current sensor arrangement 200 further comprises a connection terminal 213 having a first measuring connection 215 connected to the first measuring coil 203 and a second measuring connection 217 electrically connected to the second measuring coil 205 by means of a second winding-free connecting section 219.

The winding-free connecting sections 217 and 219 bridge a gap between the measuring coils 203, 203 in which a current-conducting lead 221 can be disposed.

The winding-free connecting section 211 can be arranged above the current-conducting lead 221 as shown in FIG. 2A, or below same as shown in FIG. 2B. The second winding-free connecting section 219 can likewise be arranged above or below current-conducting lead 221. Due to their absence of windings, the winding-free connecting sections 211, 219 contribute far less to magnetic coupling than windings 204, 206. The influence of the winding-free connecting sections 211, 219 can thus be disregarded when measuring current, particularly when they are arranged perpendicular or nearly perpendicular to the current-conducting lead.

The measuring inductors depicted in FIGS. 1A, 1B, 1C, 2A and 2B provide a measurement voltage u(t) which, in accordance with the law of induction, corresponds to a time derivative of a measurement current i(t) in the current-conducting lead 221. The measuring inductors 109, 117, 201 can therefore be considered to be modified Rogowski coils.

According to one embodiment, the measuring inductor 201 depicted in FIGS. 2A and 2B can comprise planar measuring coils 203, 205 arranged on the printed circuit board 209.

According to one embodiment, the first measuring coil 203 and second measuring coil 205 are arranged spatially or in extended manner in the circuit board 209. To this end, the windings 204, 206 on the two sides of the conductor 221, e.g. the primary conductor, can be compressed and realized as conductive paths of a circuit board. This thus results for example in spiral windings 204, 206 at different locations on the circuit board 209, which can be a printed circuit board, and an 8-shaped basic structure from above.

According to one embodiment, an integrator can be arranged downstream of the respective measuring inductor such that an output signal proportional to the measurement current is produced. The integrator can be realized by a known per se circuit having a regenerative operational amplifier with a parallel RC element in the feedback loop and a series resistor.

FIG. 3 shows a current sensor arrangement 300 comprising one measuring inductor 301, a second measuring inductor 303 and a third measuring inductor 305.

Measuring inductor 301 comprises a first measuring coil 307 with first windings 308 and a second measuring coil 309 with second windings 310. A winding-free connecting section 306 connects the measuring coils 307 and 309 in series.

The second measuring inductor 303 comprises a third measuring coil 311 with first windings 312, a fourth measuring coil 313 with second windings 314 and a winding-free connecting section 315 which connects measuring coils 311 and 313 in series.

The third measuring inductor 305 comprises a fifth measuring coil 317 with first windings 318, a sixth measuring coil 319 with second windings 320 and a winding-free connecting section 321 which electrically connects the fifth measuring coil 317 to the sixth measuring coil 319.

The current sensor arrangement 300 is designed to measure electric current in the current-conducting leads 325, 327 and 329 of a multi-phase conductor system 323. The current-conducting leads 325, 327 and 329 run through the vertices 331, 333, 335 of a notional geometrical triangle 337 in the shape of a circular arc, for example.

Measuring inductor 301 is arranged at vertex 331 and designed to measure the current in the first current-conducting lead 325. The second measuring inductor 303 is arranged at vertex 333 and designed to measure the current in the first current-conducting lead 327. The third measuring inductor 305 is arranged at vertex 335 and designed to measure the current in the first current-conducting lead 329.

As FIG. 3 shows, the second measuring coil 309 has a smaller coil diameter or fewer windings than the first measuring coil 307, the fourth measuring coil 313 has a smaller coil diameter or fewer windings than the third measuring coil 311 and the sixth measuring coil 319 has a smaller coil diameter or fewer windings than the fifth measuring coil 317.

The geometrical arrangement of the measuring inductors 301, 303 and 305 at the vertices 331, 333, 335 as well as the different diameters and/or numbers of windings realizes the measuring coils.

The geometrical optimization shown in FIG. 3 allows the magnetic coupling of current 11 through lead 325 to be reduced or nearly zero in the third measuring coil 311, the fourth measuring coil 313, the fifth measuring coil 315 as well as the sixth measuring coil 319. The area of the third measuring coil 311 can for example additionally be selected to be larger than the area of the fourth measuring coil 313 which is in turn positioned spatially closer to lead 325. Thus, two equally large induced voltage contingents of the current bearing different signs can be achieved in the third measuring coil 311 and in the fourth measuring coil 313 such that the sum of lead 325 does not act on third measuring coil 311 and fourth measuring coil 313. The symmetry of the arrangement has this applying to all three components and each current-conducting lead 325, 327, 329 (primary conductor) 10, 11, 12 acting only its own associated first and second measuring coil 308, 310, third and fourth measuring coil 311, 313, and fifth to sixth measuring coil 317, 320.

FIG. 4 shows a current sensor arrangement 400 comprising one measuring inductor 401, a second measuring inductor 403 and a third measuring inductor 405.

Measuring inductor 401 comprises a first measuring coil 407 with first windings and a second measuring coil 409 with second windings. The measuring coils 407, 409 are connected in series.

The second measuring inductor 403 comprises a third measuring coil 411 with first windings and a fourth measuring coil 413 with second windings. The measuring coils 411, 413 are connected in series.

The third measuring inductor 405 comprises a third measuring coil 415 with first windings and a fourth measuring coil 417 with second windings. The measuring coils 415, 417 are connected in series.

The measuring coils 407, 409, 411, 413, 415, 417 depicted in FIG. 4 can for example be planar measuring coils of helical or spiral design having the features described above or in the following.

According to one embodiment, the measuring coils 407, 409, 411, 413, 415, 417 are arranged spatially or in extended manner in the circuit board 425. To this end, the windings on the two sides of the respective conductor 419, 421, 423, e.g. the primary conductor, can be compressed and realized as conductive paths of the circuit board 425. This thus results for example in spiral windings at different locations on the circuit board 209, which can be a printed circuit board, and an 8-shaped basic structure from above,

The current sensor arrangement 400 is designed to measure electric current in the current-conducting leads 419, 421 and 423 of a multi-phase conductor system. The current-conducting leads 419, 421 and 423 are arranged for example in parallel.

To determine the current flowing in current-conducting leads 419, 421 and 423, the planar measuring coils 407, 409, 411, 413, 415, 417 of measuring inductors 401, 403 and 405 are respectively arranged on the sides of current-conducting leads 419, 421 and 423. The measuring inductors 401, 403 and 405 are however at least partly offset laterally along the progression of the current-conducting lead. The second measuring inductor 403 is for example laterally offset hereto relative to measuring inductor 401 and relative to the third measuring inductor. Measurements can thereby also be made in the case of closely positioned current-conducting leads 419, 421 and 423. Interference can moreover be thereby reduced.

The current sensor arrangement 400 can be arranged on a circuit board 425, for example together with current-conducting leads 419, 421 and 423.

The measuring coils 407, 409, 411, 413, 415, 417 depicted in FIG. 4 are formed opposite to the directions indicated for example by the FIG. 4 arrows. Interference originating from adjacent current-conducting leads 419, 421 and 423 can thus be reduced.

According to one embodiment, the current-conducting leads 419, 421, 423 are primary conductors and can individually or simultaneously conduct short-circuit currents bearing different signs. The measuring coils 407, 409; 411, 413; 415, 417 measure the current (measurement current) in the leads 419, 421, 423 by induction.

The measuring coils 407, 409 are series-connected in opposing relation and the induced voltages of the current-carrying primary conductor 419 overlap constructively as the magnetic field sign of lead 419 in measuring coils 407, 409 is inverse. At the same time, the field of primary lead 419 is coupled in measuring coils 411, 413. However, due to the series-opposed connection of the measuring coils 411, 413, the induced voltage is subtracted since the magnetic field sign in the second measuring inductor 401 is equal to the measuring coils 411, 413 and, in the ideal case, no voltage signal remains at second measuring inductor 401 with measuring coils 411, 413.

The same design also applies to primary leads 421 and 423 such that primary conductor 419 substantially acts only on measuring coils 407, 409, primary conductor 421 substantially only on measuring coils 411, 413 and primary conductor 423 substantially only on measuring coils 415, 416 of the third measuring inductor 405. Hence, three measurement voltages can measure and detect the different currents.

FIG. 5 shows a current sensor arrangement 500 comprising one measuring inductor 501, a second measuring inductor 503 and a third measuring inductor 505.

Measuring inductor 501 comprises a first measuring coil 507 with first windings and a second measuring coil 509 with second windings. The measuring coils 507, 509 are connected in series.

The second measuring inductor 503 comprises a third measuring coil 511 with first windings and a fourth measuring coil 513 with second windings. The measuring coils 511, 513 are connected in series.

The third measuring inductor 505 comprises a third measuring coil 515 with first windings and a fourth measuring coil 517 with second windings. The measuring coils 515, 517 are connected in series.

The measuring coils 507, 509, 511, 513, 515, 517 depicted in FIG. 5 can for example be measuring coils of helical or spiral design having the features described above or in the following.

According to one embodiment, the measuring coils 507, 509, 511, 513, 515, 517 are arranged spatially or in extended manner in the circuit board 525. To this end, the windings on the two sides of the respective conductor 519, 521, 523, e.g. the primary conductor, can be compressed and realized as conductive paths of the circuit board 525. This thus results for example in spiral windings at different locations on the circuit board 525, which can be a printed circuit board, and an 8-shaped basic structure from above.

The current sensor arrangement 500 is designed to measure electric current in the current-conducting leads 519, 521 and 523 of a multi-phase conductor system. The current-conducting leads 519, 521 and 523 are in for example a parallel arrangement.

In contrast to the embodiment depicted in FIG. 4. measuring inductors 501, 503, 505 with measuring coils 507, 509, 511, 513, 515, 517 are arranged in a series. Thus, the second measuring coil 509 and the third measuring coil 511 are for example arranged directly adjacently at different distances from the first current-conducting lead 519 or from the second current-conducting lead 521. The fourth measuring coil 513 and the fifth measuring coil 515 are analogously arranged adjacent one another at different distances from the second current-conducting lead 521 or from the third current-conducting lead 523.

The measuring coils 507, 509, 511, 513, 515, 517 depicted in FIG. 5 are formed opposite to the directions indicated for example by the FIG. 4 arrows. Interference originating from adjacent current-conducting leads 519, 521 and 523 can thus be reduced.

FIG. 6 shows a current sensor arrangement 600 comprising one measuring inductor 601, a second measuring inductor 603 and a third measuring inductor 605. Each of the measuring inductors 601, 603 and 605 comprise measuring coils which are arranged on both sides of the respective current-conducting lead 607, 609 and 611 of a multi-phase conductor system. The measuring inductors 601, 603, 605 each have for example an impedance Z.

A monitoring device 613 downstream of measuring inductors 601, 603, 605 is designed to monitor an exceedance of a current threshold by a current in the respective current-conducting lead 607, 609 and 611 based on the output signal of the respective measuring inductor 601, 603 and 605, for example a current or a voltage.

To this end, the monitoring device comprises a first monitoring path 615 for receiving the output signal of measuring inductor 601 with a first threshold detector 617 and a first diode 619 downstream of the first threshold detector 617, a second monitoring path 621 for receiving the output signal of second measuring inductor 603 with a second threshold detector 623 and a second diode 625 downstream of the second threshold detector 623 as well as a third monitoring path 627 for receiving the output signal of third measuring inductor 605 with a third threshold detector 629 and a third diode 631 downstream of the third threshold detector 629. The respective diode is representative in general of a rectifier or a rectifier circuit.

The measuring inductors 601, 603, 605 are designed to measure measurement current in the current-conducting leads 607, 609 and 611. The threshold detectors 617, 623 and 629 can have upstream integrators in order to transmit the output signals of the measuring inductors 601, 603, 605 by integration into output signals proportional to the measurement currents.

The threshold detectors 617, 623, 629 are respectively designed to generate an output current upon a representative current of the respective output signal exceeding a threshold.

The diodes 619, 625 and 631 are connected on the cathode side to a control connection 633 whereby an OR connection of the output currents of the threshold detectors 617, 623, 629 is realized. The OR connection achieves the emitting of the maximum output current at the control connection.

The threshold detectors 617, 623 and 629 compare for example the output signals of the measuring inductors 601, 603, 605 to predetermined thresholds which e.g. correspond to 10 or 20 times a fixed nominal current. Effective short circuit identification can thus be realized,

Alternatively to the threshold detectors in each of the three loops 615, 621, 627 depicted in FIG. 6, a single threshold detection can also be arranged at the control connection 633. This can be particularly advantageous when it is irrelevant at which primary conductor 607, 609, 611 the current is too high. In this case, the individual threshold detectors in 617, 623, 629 can be omitted and stages 617, 623, 629 can comprise for example only integration and amplification stages.

The current sensor arrangement 600 depicted in FIG. 6 can therefore be used as per an embodiment of short-circuit identification.

FIG. 7 depicts an extended current sensor arrangement 700 to this end comprising for example the current sensor arrangement 600 depicted in FIG. 6. A short-circuit generating mechanism 701 is provided downstream of current sensor arrangement 600. The short-circuit generating mechanism 701 is designed to short circuit at least one of the current-conducting leads 607, 609 and 611 or some of the current-conducting leads 607, 609 and 611 or all of the current-conducting leads 607, 609 and 611 in response to an output current at the control connection 633 of the current sensor arrangement 600, particularly in response to an output current occurring at control connection 633. The short circuit can for example be realized by an electrical connection between at least two of the current-conducting leads 607, 609 and 611 (phase short circuit) or by an electrical connection between at least two of the current-conducting leads 607, 609 and 611 and a ground potential.

The short-circuit generating mechanism 701 hereby comprises for example a firing pulse device 703 for generating a firing pulse for the short circuit, and short-circuit mechanism 705 downstream of the firing pulse device 703 for generating the short circuit in response to the firing pulse. The short-circuit mechanism 705 is connected to current-conducting leads 607, 609 and 611.

The firing pulse device 703 can comprise an external energy source or be fed by the short-circuit current.

In so doing, a triggerable auxiliary short circuit can be efficiently generated in order to discharge the current-conducting leads 607, 609 and 611 upon an excessive rise in current.

According to one embodiment, features of the extended current sensor arrangement 700 form their own independent short-circuit generating system.

A short-circuit protection device 705 which can comprise fuses or circuit breakers as are known per se can thereby be provided upstream of the extended current sensor arrangement 700. A supply voltage 707 can furthermore be provided at the input side which provides e.g. a three-phase supply voltage at 400 V and 50 Hz, with or without a neutral conductor.

A switching device 709 can further be provided downstream of the extended current sensor arrangement 700 and can for example be designed as a frequency converter, a contactor or a semiconductor motor switching device. An electrical load 711, for example a motor, heating elements or lamps, can be connected downstream of switching device 709.

With respect to the further details relative to the embodiments depicted in FIGS. 6 and 7, reference is made to the content of published document WO 2012/123541, the entirety of which is to be taken into account in the present description.

The short circuit detection can be implemented according to one embodiment such that shorts-to-ground can also be identified. By appropriately dimensioning the detection, it is possible to define any current value as the signal threshold for the short-circuit identification. Even relatively low short-circuit currents, e.g. 10 to 20 times the nominal current of a drive or a motor, can thereby be detected and the auxiliary short circuit generated. Thus, conventional short-circuit mechanisms, which are typically classified as critical, particularly in the case of low short-circuit currents, can achieve their full performance (as in the case of a nominal short circuit).

According to one embodiment, the measuring arrangements, e.g. the current sensor arrangements, can be used to measure short-circuit currents in a three-phase power system.

According to one embodiment, a Rogowski coil can serve as the basis for measuring current and can be realized as a compressed 8-shaped basic structure on a circuit board. While doing so may reduce precision, it does however enable economical implementation.

According to one embodiment, it is feasible for the measuring coil to be realized in triplicate for the simultaneous measuring of up to three short-circuit currents. Different arrangements are hereby possible, for example an offset arrangement, an adjacent arrangement and/or a symmetrical arrangement.

According to one embodiment, each measuring coil detects its own associated short-circuit current significantly stronger than the currents of adjacent leads. The factor can thereby amount to two up to multiple orders of magnitude. This can be attributed to the Rogowski structure, e.g. the 8-shape as well as the enclosed conductor.

According to one embodiment, the current sensor arrangement encompasses three measurement signals able to be integrated and rectified.

According to one embodiment, the current sensor arrangement comprises an electronic circuit which compares the measurement signals.

According to one embodiment, the current sensor arrangement comprises an electronic circuit which is fed by the strongest measurement signal to evaluate a short circuit.

According to one embodiment, an evaluation signal activates an auxiliary short circuit.

According to one embodiment, the entire circuit, e.g. the current sensor arrangement, can be of passive or active design.

According to one embodiment, a passive design can be realized by an RC element integration and simple diodes or by a simple coupling.

According to one embodiment, an active design can comprise integration via an operation amplifier or a microprocessor or uP respectively.

1. A current measuring arrangement comprising a measuring inductor comprising:
a first measuring coil;
a second measuring coil;
wherein the first measuring coil and the second measuring coil are electrically connected in series and have different coil properties.

2. The current measuring arrangement according to claim 1, wherein the first measuring coil and the second measuring coil have at least one of different inductances, different numbers of windings, different surface areas different coil diameters.

3. The current measuring arrangement according to claim 1, wherein the first measuring coil and the second measuring coil are electrically connected by means of a winding-free section.

4. The current measuring arrangement according to claim 1, wherein the first measuring coil is planar and includes windings arranged in a first plane, and wherein the second measuring coil is planar and includes windings arranged in a second plane.

5. The current measuring arrangement according to claim 4, wherein the first windings are of at least one of planar helical and spiral structure in the first plane, and wherein the second windings are of at least one of planar helical and spiral structure in the second plane.

6. The measuring arrangement according to claim 5, wherein the first plane and the second plane are at least one of parallel to each other and run at a predetermined angle to one another.

7. The measuring arrangement according to claim 1, wherein the first measuring coil and the second measuring coil are connected in series by a first winding-free connecting section, wherein a connection terminal having a first measuring connection connected to the first measuring coil and a second measuring connection connected to the second measuring coil by means of a second winding-free connecting section.

8. The measuring arrangement according to claim 7, wherein the current-conducting lead is arranged at least in one of above and below the respective winding-free connecting section.

9. The measuring arrangement according to claim 1 further comprises a dielectric substrate, wherein the measuring inductor is supported by the dielectric substrate, and wherein the first measuring coil and the second measuring coil are supported by the dielectric substrate.

10. A current sensor arrangement according to claim 1 comprising a second measuring inductor and a third measuring inductor, wherein the second measuring inductor comprises a third planar measuring coil with first windings which are arranged in the first plane, a fourth planar measuring coil with second windings which are arranged in the second plane, and a winding-free connecting section which electrically connects the third planar measuring coil to the fourth planar measuring coil, wherein the third measuring inductor comprises a fifth planar measuring coil with first windings which are arranged in the first plane, a sixth planar measuring coil with second windings which are arranged in the second plane, and a winding-free connecting section which electrically connects the fifth planar measuring coil to the sixth planar measuring coil, and wherein each measuring inductor is provided to measure a current in a respective current-conducting lead of a multi-phase conductor system.

11. The current sensor arrangement according to claim 10, wherein the first planar measuring coil and the second planar measuring coil are arranged on both sides of a first current-conducting lead of the multi-phase conductor system, wherein the third planar measuring coil and the fourth planar measuring coil are arranged on both sides of a second current-conducting lead of the multi-phase conductor system, and wherein the fifth planar measuring coil and the sixth planar measuring coil are arranged on both sides of a third current-conducting lead of the multi-phase conductor system.

12. The current sensor arrangement according to claim 10, wherein the second planar measuring coil and the third planar measuring coil are arranged adjacent each other at different distances to at least one of the first current-conducting lead and to the second current-conducting lead, and wherein the fourth planar measuring coil and the fifth planar measuring coil are arranged adjacent each other at different distances to at least one of the second current-conducting lead and to the third current-conducting lead.

13. The current sensor arrangement according to claim 10, wherein the second measuring inductor is laterally offset relative to measuring inductor and relative to the third measuring inductor.

14. The current sensor arrangement according to claim 13, wherein the third measuring coil is arranged directly adjacent the first current-conducting lead and wherein the fourth measuring coil is arranged directly adjacent the third current-conducting lead.

15. The current sensor arrangement according to claim 10, wherein the current-conducting leads of the mufti-phase conductor system run through the vertices of a geometrical triangle, and wherein the second measuring inductor and the third measuring inductor are arranged at the vertices of the planar geometrical triangle.

16. The current sensor arrangement according to claim 10, wherein the second planar measuring coil includes at least one of a smaller coil diameter and fewer windings than the first planar measuring coil, wherein the fourth planar measuring coil includes at least one of a smaller coil diameter and fewer windings than the third planar measuring coil, and wherein the sixth planar measuring coil includes at least one of a smaller coil diameter and fewer windings than the fifth planar measuring coil.

17. The current sensor arrangement according claim 10, wherein the respective measuring inductor is designed to emit an output signal, which is dependent upon the intensity of the current in the respective current-conducting lead, wherein the current sensor arrangement further comprises a monitoring device designed to monitor the exceedance of a current threshold by an electric current in the respective current-conducting lead based on the output signal of the respective measuring inductor.

18. The current sensor arrangement according to claim 17, wherein the monitoring device comprises:
a first monitoring path for receiving the output signal of the measuring inductor with a first threshold detector and a first diode downstream of the first threshold detector;
a second monitoring path for receiving the output signal of the second measuring inductor with a second threshold detector and a second diode downstream of the second threshold;
a third monitoring path for receiving the output signal of the third measuring inductor with a third threshold detector and a third diode downstream of the third threshold detector; and
a control connection with which the cathode of the first diode, the cathode of the second diode, and the cathode of the third diode are electrically connected;
wherein the respective threshold detector is configured to generate an output current upon exceeding a threshold by a current represented by the respective output signal.

19. The current sensor arrangement according to claim 18, comprising a short-circuit generating device downstream of the control connection and designed to short circuit at least one of the current-conducting leads in response to an output current at the control connection.

20. the current sensor arrangement according to claim 9, wherein the dielectric substrate is a circuit board.
